(19) United States
(12) Patent Application Publication
(10) Pub. No.: US 2025/0126905 A1
(43) Pub. Date: Apr. 17, 2025

(54) SEMICONDUCTOR DEVICE AND ELECTRONIC APPARATUS

(71) Applicant: SONY SEMICONDUCTOR SOLUTIONS CORPORATION, KANAGAWA (JP)

(72) Inventors: HIDETOSHI OISHI, KANAGAWA (JP); AKITO SHIMIZU, KANAGAWA (JP)

(21) Appl. No.: 18/834,732

(22) PCT Filed: Dec. 22, 2022
(86) PCT No.: PCT/JP2022/047352

§ 371 Date: Jul. 31, 2024

(30) Foreign Application Priority Data
Feb. 9, 2022 (JP) 2022-018681

(51) Int. Cl. H10F 39/00; H04N 25/60

(52) U.S. Cl. CPC H10F 39/8037; H04N 25/60; H10F 39/8063

(57) ABSTRACT

To achieve high integration and improvement in noise resistance. A semiconductor device includes first and second field-effect transistors. In addition, each of the first and second field-effect transistors includes a channel formation portion provided in a semiconductor including an upper surface and side surfaces, a gate electrode provided over the upper surface and the side surfaces in one direction of the semiconductor, and a gate insulating film provided between the semiconductor and the gate electrode. In addition, a width, in the one direction, of the upper surface of the semiconductor layer overlapping the gate electrode of the first transistor is smaller than a width, in the one direction, of the upper surface of the semiconductor layer overlapping the gate electrode of the second transistor, and a film thickness of the gate insulating film of the second transistor is smaller than a film thickness of the gate insulating film of the first transistor.

### TECHNICAL FIELD

The present technology (the technology in the present disclosure) relates to a semiconductor device and an electronic apparatus, and more particularly to a technology effective when applied to a semiconductor device including fin field-effect transistors and an electronic apparatus including the semiconductor device.

### BACKGROUND ART

As a semiconductor device, for example, a solid-state imaging device called a CMOS image sensor is known. The CMOS image sensor includes a pixel circuit (reading circuit) that reads signal charge generated by a photoelectric conversion element as a result of photoelectric conversion and that converts the signal charge into a pixel signal based on the signal charge. The reading circuit includes pixel transistors such as an amplification transistor, a selection transistor, and a reset transistor.

In addition, as a field-effect transistor mounted on a semiconductor device, a fin field-effect transistor (Fin-FET) is known in which a gate electrode is provided in an island semiconductor (fin) via a gate insulating film. Because the fin field-effect transistor can improve electric field controllability of a gate to improve short channel characteristics and shorten a gate length Lg (channel length L) to achieve a necessary operation, planar size can be shrunk, which is useful for high integration.

Patent Document 1 discloses a solid-state imaging device in which an amplification transistor included in a pixel circuit is achieved by a fin field-effect transistor.

### CITATION LIST

### Patent Document

Patent Document 1: Japanese Patent Application Laid-Open No. 2017-183636

### SUMMARY OF THE INVENTION

### Problems to be Solved by the Invention

A pixel circuit, by the way, includes pixel transistors for different purposes. More specifically, a pixel circuit includes pixel transistors such as a selection transistor and a reset transistor that function as switching elements and an amplification transistor that functions as an amplification element.

In a case where the pixel transistors (the selection transistor and the reset transistor) that function as switching elements are achieved by a fin field-effect transistor, electric field controllability of a gate can be improved by reducing width of a semiconductor (width of a fin), and a transistor excellent in suppressing a short channel effect can be constructed. A gate length Lg (channel length L), therefore, can be shortened, and planar size can be shrunk. In a case where a film thickness of a gate insulating film is small, however, it becomes difficult to satisfy an element of reliability of the gate insulating film. In addition, conversely, by increasing the width of the semiconductor, suppression of the short channel effect is deteriorated, and it becomes difficult to shorten (shortening) length of the gate length Lg (channel length L).

In a case where the amplification transistor that functions as an amplification element is achieved by a fin field-effect transistor, on the other hand, effective channel area (channel length L×channel width W) is undesirably reduced by reducing the width of the semiconductor, and noise characteristics such as 1/f noise and random telegraph signal (RTS) noise, which are important indicators of the amplification transistor, are assumed to deteriorate.

The present engineer has focused on purposes of transistors and achieved the present technology.

An object of the present technology is to achieve high integration and improvement in noise resistance.

### Solutions to Problems

(1) A semiconductor device according to an aspect of the present technology includes:
first and second field-effect transistors,
each of the first and second field-effect transistors includes
a channel formation portion provided in a semiconductor including an upper surface and side surfaces,
a gate electrode provided over the upper surface and the side surfaces in one direction of the semiconductor, and
a gate insulating film provided between the semiconductor and the gate electrode,
in which a width, in the one direction, of the upper surface of the semiconductor layer overlapping the gate electrode of the first transistor is smaller than a width, in the one direction, of the upper surface of the semiconductor layer overlapping the gate electrode of the second transistor, and
a film thickness of the gate insulating film of the second transistor is smaller than a film thickness of the gate insulating film of the first transistor.
(2) An electronic apparatus according to another aspect of the present technology includes the semiconductor device, an optical system that forms an image of image light from a subject on the semiconductor device, and a signal processing circuit that performs signal processing on a signal output from the semiconductor device.

### BRIEF DESCRIPTION OF DRAWINGS

FIG. 1 is a schematic plan view illustrating a configuration example of a semiconductor device according to a first embodiment of the present technology.

FIG. 2 is a schematic vertical cross-sectional view illustrating a vertical cross-sectional structure taken along line a1-a1 in FIG. 1.

FIG. 3 is a schematic vertical cross-sectional view illustrating a vertical cross-sectional structure taken along line b1-b1 in FIG. 1.

FIG. 4 is a schematic vertical cross-sectional view illustrating a vertical cross-sectional structure taken along line c1-c1 in FIG. 1.

FIG. 5 is a schematic plan view illustrating a configuration example of a semiconductor device according to a second embodiment of the present technology.

FIG. 6 is a schematic vertical cross-sectional view illustrating a vertical cross-sectional structure taken along line a5-a5 in FIG. 5.

FIG. 7 is a schematic plan layout diagram illustrating a configuration example of a solid-state imaging device according to a third embodiment of the present technology.

FIG. 8 is a block diagram illustrating a configuration example of the solid-state imaging device according to the third embodiment of the present technology.

FIG. 9 is an equivalent circuit diagram illustrating a configuration example of a pixel and a pixel circuit of the solid-state imaging device according to the third embodiment of the present technology.

FIG. 10 is a schematic vertical cross-sectional view illustrating a vertical cross-sectional structure of a pixel array unit of the solid-state imaging device according to the third embodiment of the present technology.

FIG. 11 is a schematic vertical cross-sectional view illustrating a configuration example of a solid-state imaging device according to a fourth embodiment of the present technology.

FIG. 12 is a diagram illustrating a schematic configuration of an electronic apparatus according to a fifth embodiment of the present technology.

### MODE FOR CARRYING OUT THE INVENTION

Embodiments of the present technology will be described in detail hereinafter with reference to the drawings.

In the illustration of the drawings referred to in the following description, the same or similar parts are given the same or similar reference signs. It should be noted, however, that the drawings are schematic, and a relationship between thickness and a planar dimension, a ratio of thicknesses of individual layers, and the like are different from actual ones. Specific thicknesses and dimensions, therefore, should be determined in consideration of the following description.

In addition, it is needless to say that dimensional relationships and ratios are partly different between the drawings. In addition, effects described herein are merely examples and not limited, and other effects may also be produced.

In addition, the following embodiments illustrate devices and methods for embodying the technical idea of the present technology, and do not limit configurations to those described below. That is, the technical idea of the present technology may be modified in various ways within the technical scope described in the claims.

In addition, definitions of directions such as upward and downward in the following description are merely employed for convenience of description, and do not limit the technical idea of the present technology. It is needless to say, for example, that upward and downward become leftward and rightward if a target is rotated by 90° and observed, and upward and downward are switched if a target is rotated by 180° and observed.

In addition, although a case where a first conductivity type is a p-type and a second conductivity type is an n-type will be described as conductivity types of semiconductors in the following embodiments, an opposite relationship may be selected for the conductivity types, and the first conductivity type may be the n-type and the second conductivity type may be the p-type, instead.

In addition, in the following embodiments, among three directions perpendicular to one another in space, a first direction and a second direction perpendicular to each other in the same plane will be defined as an X direction and a Y direction, respectively, and a third direction perpendicular to the first direction and the second direction will be defined as a Z direction. Furthermore, in the following embodiments, a thickness direction of a semiconductor layer 2, which will be described later, will be described as the Z direction.

### First Embodiment

In this first embodiment, an example will be described where the present technology is applied to a semiconductor device including first and second field-effect transistors having different purposes will be described.

### Overall Configuration of Semiconductor Device

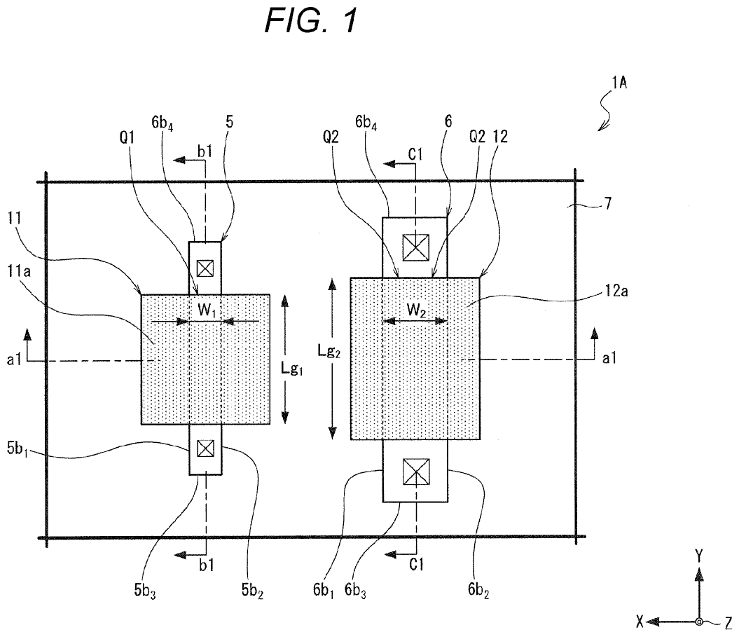

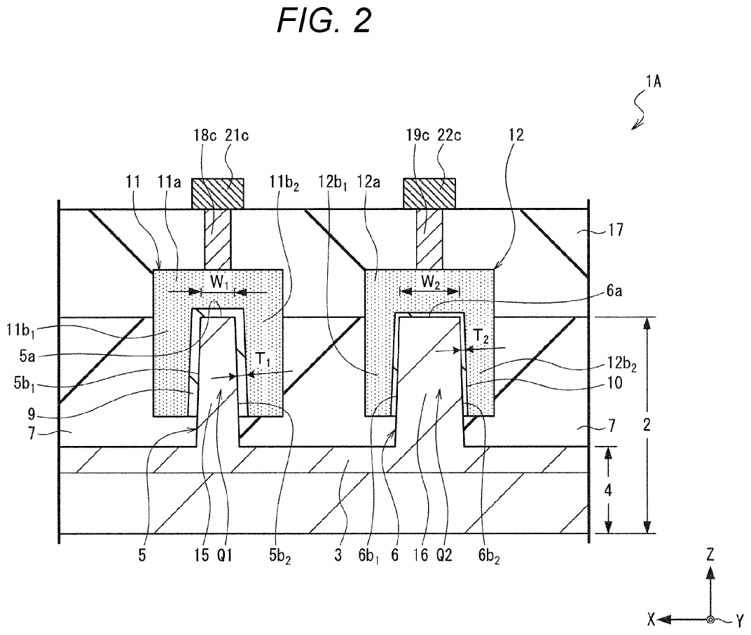

First, an overall configuration of the semiconductor device will be described with reference to FIGS. 1 to 4. In FIG. 1, illustration of an insulating layer 17, contact electrodes (18a, 18b, 18c, 19a, 19b, and 19c), and wires (21a, 21b, 21c, 22a, 22b, and 22c) illustrated in FIGS. 2 to 4 is omitted for convenience of description.

As illustrated in FIGS. 1 and 2, a semiconductor device 1A according to the first embodiment includes a semiconductor layer 2 and first and second field-effect transistors Q1 and Q2 mounted on the semiconductor layer 2.

### Semiconductor Layer

As illustrated in FIGS. 1 to 4, the semiconductor layer 2 includes a base 4 extending in two dimensions in the X and Y directions, and island semiconductors 5 and 6 protruding upward (Z direction) from the base 4. The semiconductors 5 and 6 are provided separately from each other in a two-dimensional plane. Although not limited to this, the semiconductors 5 and 6 in the first embodiment extend, for example, in the Y direction and are arranged parallel to each other with a certain gap provided therebetween in the X direction.

As illustrated in FIGS. 1, 2, and 3, the semiconductor 5 is a mesa-like rectangular parallelepiped having an upper surface 5a and four side surfaces 5b₁, 5b₂, 5b₃, and 5b₄. Similarly, as illustrated in FIGS. 1, 2, and 4, the semiconductor 6 is a mesa-like rectangular parallelepiped having an upper surface 6a and four side surfaces 6b₁, 6b₂, 6b₃, and 6b₄.

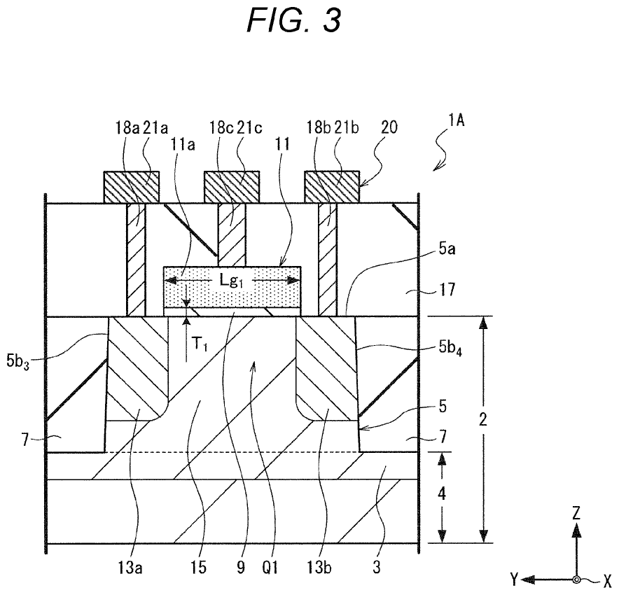

As illustrated in FIGS. 2 and 3, in the semiconductor 5, among the four side surfaces 5b₁, 5b₂, 5b₃, and 5b₄, the two side surfaces 5b₁ and 5b₂ are located on opposite sides in the X direction, and the other two side surfaces 5b₃ and 5b₄ are located on opposite sides in the Y direction. Each of the four side surfaces 5b₁, 5b₂, 5b₃, and 5b₄ is also inclined such that an upper surface 5a side thereof is located inside a base 4 side thereof.

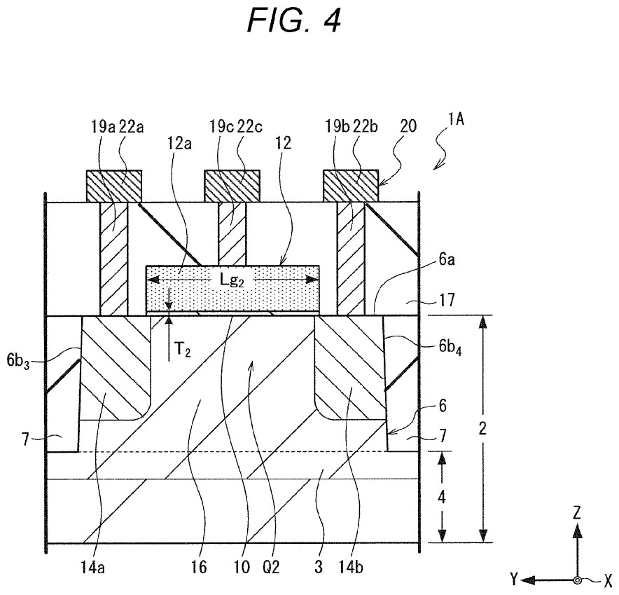

As illustrated in FIGS. 2 and 4, among the four side surfaces 6b₁, 6b₂, 6b₃, and 6b₄ of the semiconductor 6, the two side surfaces 6b₁ and 6b₂ are located on opposite sides in the X direction, and the other two side surfaces 6b₃ and 6b₄ are located on opposite sides in the Y direction. Each of the four side surfaces 6b₁, 6b₂, 6b₃, and 6b₄ is also inclined such that an upper surface 6a side thereof is located inside a base 4 side thereof.

Each of the semiconductors 5 and 6 can be formed by selectively etching the semiconductor layer 2 to such a depth that the base 4 remains. Although not limited to this, the semiconductor layer 2 is a semiconductor substrate that uses silicon (Si), for example, as a semiconductor material, single crystal, for example, as crystallinity, and the p-type, for example, as a conductivity type.

As illustrated in FIGS. 2 to 4, the semiconductor layer 2 is provided with p-type well regions 3, which are, for example, p-type semiconductor regions. The p-type well regions 3 are provided all over the semiconductors 5 and 6 and provided all over a surface of the base 4 on a semiconductors 5 and 6 side of the base 4. The p-type well regions 3 are separated from a back surface of the base 4 opposite the semiconductors 5 and 6 side of the base 4.

### Insulating Layer

As illustrated in FIGS. 2 to 4, an insulating layer 7 is provided on the base 4 of the semiconductor layer 2 in such a way as to surround the semiconductors 5 and 6. A surface of the insulating layer 7 opposite a base 4 side of the semiconductor layer 2 is planarized, and the insulating layer 7 has a film thickness substantially equal to height (protrusion) of each of the semiconductors 5 and 6. The insulating layer 7 is, for example, a silicon oxide (SiO₂) film.

The insulating layer 17 is provided on the insulating layer 7 in such a way as to cover heads 11a and 12a of gate electrodes 11 and 12 of the first and second field-effect transistors Q1 and Q2, respectively, which will be described later. The insulating layer 17, too, is, for example, a silicon oxide (SiO₂) film.

A first wiring layer including the wires 21a, 21b, 21c, 22a, 22b, and 22c is provided on the insulating layer 17. The wires 21a, 21b, 21c, 22a, 22b, and 22c of the wiring layer are, for example, metal films of aluminum (Al), copper (Cu), or the like or alloy films mainly containing Al or Cu.

### Field-Effect Transistors

Although not limited to this, each of the first and second field-effect transistors Q1 and Q2 illustrated in FIG. 1 is of, for example, an n-channel conductivity type. In addition, each of the first and second field-effect transistors Q1 and Q2 is a metal-oxide-semiconductor field-effect transistor (MOSFET) in which a gate insulating film is a silicon oxide (SiO₂) film.

The first and second field-effect transistors Q1 and Q2 may be of a p-channel conductivity type, instead. Alternatively, the first and second field-effect transistors Q1 and Q2 may be a metal-insulator-semiconductor FET (MISFET) in which a gate insulating film is a silicon nitride film or a multilayer film (composite film) including a silicon nitride (Si₃N₄) film and a silicon oxide film.

As illustrated in FIGS. 1 and 2, the first field-effect transistor Q1 is provided in the semiconductor 5. The second field-effect transistor Q2, on the other hand, is provided in the semiconductor 6, which is different from the semiconductor 5. That is, in the first embodiment, the first field-effect transistor Q1 and the second field-effect transistor Q2 are individually provided in the different semiconductor 5 and 6, respectively.

Each of the first and second field-effect transistors Q1 and Q2 is used as a constituent element of a certain circuit. In addition, circuits mounted on the semiconductor device 1 include circuits including field-effect transistors for different purposes. In the first embodiment, for example, the first field-effect transistor Q1 functions as a switching element, and the second field-effect transistor Q2 functions as an amplification element. That is, in the first embodiment, the first field-effect transistor Q1 and the second field-effect transistor Q2 having different purposes are mounted.

### First Field-Effect Transistor

As illustrated in FIGS. 1, 2, and 3, the first field-effect transistor Q1 includes a channel formation portion 15 provided in the semiconductor 5, the gate electrode 11 provided over the upper surface 5a and the side surfaces 5b₁ and 5b₂ of the semiconductor 5 in a lateral direction (X direction) intersecting a longitudinal direction (Y direction) of the semiconductor 5, and a gate insulating film 9 provided between the semiconductor 5 and the gate electrode 11. In addition, the first field-effect transistor Q1 further includes a pair of main electrode regions 13a and 13b provided in the semiconductor 5 on both sides in a gate length direction of the gate electrode 11 (a channel length direction of the channel formation portion 15). The pair of main electrode regions 13a and 13b functions as a source region and a drain region, respectively. In addition, the pair of main electrode regions 13a and 13b is, for example, n-type semiconductor regions formed by selectively introducing an n-type impurity into the semiconductor 5. The first field-effect transistor Q1 is of a fin type in which the gate electrode 11 is provided on the island semiconductor (fin) 5 via the gate insulating film 9.

Here, in the first embodiment, the semiconductor 5 corresponds to a specific example of a “semiconductor” in the present technology. In addition, the lateral direction (X direction) of the semiconductor 5 intersecting the longitudinal direction (Y direction) corresponds to a specific example of “one direction of a semiconductor” in the present technology.

The first field-effect transistor Q1 is, for example, of an enhancement type (normally-off type) in which a drain current flows by applying a gate voltage higher than or equal to a threshold voltage to the gate electrode 11 or a depression type (normally-off type) in which a drain current flows without applying a voltage to the gate electrode 11. Although not limited to this, the enhancement type, for example, is employed in the first embodiment. In the case of the enhancement type, in the first field-effect transistor Q1, a channel (inversion layer) electrically connecting the pair of main electrode regions 13a and 13b to each other is formed (induced) in the channel formation portion 15 by a voltage applied to the gate electrode 11, and a current (drain current) flows from a drain region side (e.g., a main electrode region 13a side) to a source region side (e.g., the main electrode region 13b) through the channel of the channel formation portion 15.

### Gate Electrode and Gate Insulating Film

Although not limited to this, the gate electrode 11 includes, as illustrated in FIGS. 1, 2, and 3, for example, the head (first portion) 11a provided on an upper surface 5a side of the semiconductor 5 via the gate insulating film 9 and two legs (second portions) 11b₁ and 11b₂ that are integrated with the head 11a and that are provided outside the two side surfaces 5b₁ and 5b₂, which are located on opposite sides in the X direction of the semiconductor 5, via the gate insulating film 9. That is, the gate electrode 11 is provided over the upper surface 5a and the two side surfaces 5b₁ and 5b₂ of the semiconductor 5 and also has a C-shaped vertical cross-section along the X direction. The gate electrode 11 is, for example, a polycrystalline silicon film doped with an impurity for decreasing a resistance.

Each of the two legs 11b₁ and 11b₂ is embedded in the insulating layer 7. The head 11a, on the other hand, protrudes upward from the insulating layer 7.

The gate insulating film 9 is provided over the upper surface 5a and the two side surfaces 5b₁ and 5b₂ of the semiconductor 5 between the semiconductor 5 and the gate electrode 11. The gate insulating film 9 is, for example, a silicon oxide film.

### Second Field-Effect Transistor

As illustrated in FIGS. 1, 2, and 4, the second field-effect transistor Q2 includes a channel formation portion 16 provided in the semiconductor 6, the gate electrode 12 provided over the upper surface 6a and the side surfaces 6b₁ and 6b₂ of the semiconductor 6 in a lateral direction (X direction) intersecting a longitudinal direction (Y direction) of the semiconductor 6, and a gate insulating film 10 provided between the semiconductor 6 and the gate electrode 12. In addition, the second field-effect transistor Q2 further includes a pair of main electrode regions 14a and 14b provided in the semiconductor 6 on both sides in a gate length direction of the gate electrode 12 (a channel length direction of the channel formation portion 16). The pair of main electrode regions 14a and 14b functions as a source region and a drain region, respectively. In addition, the pair of main electrode regions 14a and 14b is, for example, n-type semiconductor regions formed by selectively introducing an n-type impurity into the semiconductor 6. Similarly to the first field-effect transistor Q1, the second field-effect transistor Q2, too, is of the fin type in which the gate electrode 12 is provided on the island semiconductor (fin) 6 via the gate insulating film 10.

Here, in the first embodiment, the semiconductor 6 corresponds to another specific example of the “semiconductor” in the present technology. In addition, the lateral direction (X direction) of the semiconductor 6 intersecting the longitudinal direction (Y direction) corresponds to another specific example of the “one direction of a semiconductor” in the present technology.

The second field-effect transistor Q2 is, for example, of the enhancement type (normally-off type) or the depression type (normally-off type). Although not limited to this, the enhancement type, for example, is employed in the first embodiment. In the case of the enhancement type, in the second field-effect transistor Q2, a channel (inversion layer) electrically connecting the pair of main electrode regions 14a and 14b to each other is formed (induced) in the channel formation portion 16 by a voltage applied to the gate electrode 12, and a current (drain current) flows from a drain region side (e.g., a main electrode region 14a side) to a source region side (e.g., the main electrode region 14b) through the channel of the channel formation portion 16.

### Gate Electrode and Gate Insulating Film

Although not limited to this, the gate electrode 12 includes, as illustrated in FIGS. 1, 2, and 4, for example, the head (first portion) 12a provided on an upper surface 6a side of the semiconductor 6 via the gate insulating film 10 and two legs (second portions) 12b₁ and 12b₂ that are integrated with the head 12a and that are provided outside the two side surfaces 6b₁ and 6b₂, which are located on opposite sides in the X direction of the semiconductor 6, via the gate insulating film 10. That is, the gate electrode 12 is provided over the upper surface 6a and the two side surfaces 6b₁ and 6b₂ of the semiconductor 6 and also has a C-shaped vertical cross-section along the X direction. The gate electrode 12 is, for example, a polycrystalline silicon film doped with an impurity for decreasing a resistance.

Each of the two legs 12b₁ and 12b₂ is embedded in the insulating layer 7. The head 12a, on the other hand, protrudes upward from the insulating layer 7.

The gate insulating film 10 is provided over the upper surface 6a and the two side surfaces 6b₁ and 6b₂ of the semiconductor 6 between the semiconductor 6 and the gate electrode 12. The gate insulating film 10 is, for example, a silicon oxide film.

### Differences in Configuration

In the first and second field-effect transistors Q1 and Q2, as illustrated in FIGS. 1 and 2, a width W₁, in the lateral direction (X direction) of the semiconductor 5 intersecting the longitudinal direction (Y direction), of the upper surface 5a of the semiconductor 5 overlapping the gate electrode 11 of the first field-effect transistor Q1 in plan view is smaller (narrower) than a width W₂, in the lateral direction (X direction) of the semiconductor 6 intersecting the longitudinal direction (Y direction), of the upper surface 6a of the semiconductor 6 overlapping the gate electrode 12 of the second field-effect transistor Q2 in plan view. In other words, the width W₂ of the upper surface 6a of the semiconductor 6 is greater (wider) than the width W₁ of the upper surface 5a of the semiconductor 5. Although not limited to this, the width W₁ of the upper surface 5a of the semiconductor 5 in the first embodiment is constant as a design value from one end (side surface 5b₃ side) to another end (side surface 5b₄ side) in the longitudinal direction of the semiconductor 5. The width W₂ of the upper surface 6a of the semiconductor 6, too, is constant as a design value from one end (side surface 6b₃ side) to another end (side surface 6b₄ side) in the longitudinal direction of the semiconductor 6.

Here, in the first embodiment, the width W₁ of the semiconductor 5 and the width W₂ of the semiconductor 6 correspond to specific examples of a “width of an upper surface of a semiconductor in one direction” in the present technology.

In addition, as illustrated in FIGS. 2 to 4, a film thickness T₂ of the gate insulating film 10 of the second field-effect transistor Q2 is smaller than a film thickness T₁ of the gate insulating film 9 of the first field-effect transistor Q1. In other words, the film thickness T₁ of the gate insulating film 9 is greater than the film thickness T₂ of the gate insulating film 10. A relative difference in film thickness between the gate insulating film 9 and the gate insulating film 10 is constant as a design value over the head (11a or 11b) of the gate electrode (11 or 12) and the two legs (11b₁ and 11b₂ or 12b₁ and 12b₂) of each of the first and second field-effect transistors Q1 and Q2.

In addition, although not limited to this, a gate length Lg₂ of the gate electrode 12 of the second field-effect transistor Q2 is, as illustrated in FIGS. 3 and 4, longer (greater) than a gate length Lg₁ of the gate electrode 11 of the first field-effect transistor Q1. In other words, the gate length Lg₁ of the gate electrode 11 of the first field-effect transistor Q1 is shorter (smaller) than the gate length Lg₂ of the gate electrode 12 of the second field-effect transistor Q2.

Here, in the first fin field-effect transistor Q1, a length between the pair of main electrode regions 13a and 13b is a channel length L (≈gate length Lg₁), and a length including the width W₁ of the upper surface 5a of the semiconductor 5 and heights of the two side surfaces 5b₁ and 5b₂ (length of a contour of the semiconductor 5) in a region where the gate electrode 11 and the semiconductor 5 overlap each other in three dimensions is a channel width W (≈gate width).

In addition, in the second fin field-effect transistor Q2, a length between the pair of main electrode regions 14a and 14b is a channel length (≈gate length Lg₂), and a length including the width W₂ of the upper surface 6a of the semiconductor 6 and heights of the two side surfaces 6b₁ and 6b₂ (length of a contour of the semiconductor 6) in a region where the gate electrode 12 and the semiconductor 6 overlap each other in three dimensions is a channel width W (≈gate width).

In the first and second fin field-effect transistors Q1 and Q2, therefore, since the channel width W is reduced by reducing the width of the semiconductors 5 and 6, channel area (channel length L×channel width W) can be reduced. Conversely, since the channel width W is increased by increasing the width of the semiconductors 5 and 6, the channel area (channel length L×channel width W) can be increased.

In addition, in the first and second fin field-effect transistors Q1 and Q2, since the channel width W is reduced by reducing the height of the semiconductors 5 and 6, the channel area (channel length L×channel width W) can be reduced. Conversely, since the channel width W is increased by increasing the height of the semiconductors 5 and 6, the channel area (channel length L×channel width W) can be increased.

Note that in the first embodiment, the gate length Lg₂ of the gate electrode 12 of the second field-effect transistor Q2 is greater than the gate length Lg₁ of the gate electrode 11 of the first field-effect transistor Q1. In addition, the gate length Lg₁ of the gate electrode 11 of the first field-effect transistor Q1 is preferably, for example, 200 nm or smaller.

In addition, a difference between the width W₁ of the upper surface 5a of the semiconductor 5 overlapping the gate electrode 11 of the first field-effect transistor Q1 and the width W₂ of the upper surface 6a of the semiconductor 6 overlapping the gate electrode 12 of the second field-effect transistor Q2 is preferably 10 nm or larger.

In addition, a difference between the film thickness T₁ of the gate insulating film 9 of the first field-effect transistor Q1 and the film thickness T₂ of the gate insulating film 10 of the second field-effect transistor Q2 is preferably 1 nm or larger.

### Contact Electrodes and Wires

In the first field-effect transistor Q1, the gate electrode 11 is, as illustrated in FIGS. 2 and 3, electrically connected to the wire 21c on the insulating layer 17 via the contact electrode 18c provided on the insulating layer 17. In addition, as illustrated in FIG. 3, the main electrode region 13a of the pair of main electrode regions 13a and 13b is electrically connected to the wire 21a on the insulating layer 17 via the contact electrode 18a provided on the insulating layer 17. The other main electrode region 13b of the pair of main electrode regions 13a and 13b, on the other hand, is electrically connected to the wire 21b on the insulating layer 17 via the contact electrode 18b provided on the insulating layer 17.

In the second field-effect transistor Q2, the gate electrode 12 is, as illustrated in FIGS. 2 and 4, electrically connected to the wire 22c on the insulating layer 17 via the contact electrode 19c provided on the insulating layer 17. In addition, as illustrated in FIG. 4, the main electrode region 14a of the pair of main electrode regions 14a and 14b is electrically connected to the wire 22a on the insulating layer 17 via the contact electrode 19a provided on the insulating layer 17. The other main electrode region 14b of the pair of main electrode regions 14a and 14b, on the other hand, is electrically connected to the wire 22b on the insulating layer 17 via the contact electrode 19b provided on the insulating layer 17.

As a material of the contact electrodes 18a, 18b, 18c, 19a, 19b, and 19c, for example, a high melting point metal film such as titanium (Ti) or tungsten (W) may be used.

### Main Effects in the First Embodiment

Next, main effects in the first embodiment will be described.

The first and second field-effect transistors Q1 and Q2 are of the fin type. In addition, as illustrated in FIG. 2, in the first field-effect transistor Q1, the width W₁ of the upper surface 5a of the semiconductor 5 overlapping the gate electrode 11 is smaller than the width W₂ of the upper surface 6a of the semiconductor 6 overlapping the gate electrode 12 of the second field-effect transistor Q2. As described above, by reducing the width W₁ of the upper surface 5a of the semiconductor 5, controllability of the gate improves and the first field-effect transistor Q1 excellent in suppressing a short channel effect compared to the second field-effect transistor Q2 can be constructed. The gate length, therefore, can be reduced to shrink planar size of the first field-effect transistor Q1. As a result of the shrinkage of the first field-effect transistor Q1 in planar size, area occupied by a circuit including the first field-effect transistor Q1 can be reduced, which contributes to high integration of the semiconductor device 1A.

In addition, since the film thickness T₁ of the gate insulating film 9 of the first field-effect transistor Q1 is larger than the film thickness T₂ of the gate insulating film 10 of the second field-effect transistor Q2, it is possible to suppress a decrease in reliability of the gate insulating film 10 due to the shrinkage in plane size.

It is therefore possible to shrink the first field-effect transistor Q1 in planar size while ensuring reliability of the gate insulating film 9.

In the second field-effect transistor Q2, on the other hand, the width W₂ of the upper surface 6a of the semiconductor 6 overlapping the gate electrode 12 is, as illustrated in FIG. 2, greater than the width of the upper surface 5a of the semiconductor 5 overlapping the gate electrode 11 of the first field-effect transistor Q1. As described above, by increasing the width W₂ of the upper surface 6a of the semiconductor 6, the channel area (L×W) can be increased, and the second field-effect transistor Q2 excellent in noise resistance with respect to 1/f noise, RIS noise, and the like compared to the first field-effect transistor Q1 can be constructed.

In addition, since the film thickness T₂ of the gate insulating film 10 of the second field-effect transistor Q2 is smaller than the film thickness T₁ of the gate insulating film 9 of the first field-effect transistor Q1, it is possible to suppress deterioration in noise resistance with respect to 1/f noise, random telegraph signal (RIS) noise, and the like due to an increase in the film thickness of the gate insulating film 10.

Here, in field-effect transistors, it is generally known that noise resistance with respect to 1/f noise, RIS noise, and the like can be made excellent by increasing channel area. In addition, it is generally known that noise resistance with respect to 1/f noise, RIS noise, and the like deteriorates when film thickness of a gate insulating film is increased.

In the second field-effect transistor Q2, therefore, it is possible to improve noise resistance while securing the channel width W (gate width Wg).

With the semiconductor device 1A according to the first embodiment, therefore, high integration and improvement in noise resistance can be achieved by mounting both the first field-effect transistor Q1 and the second field-effect transistor Q2.

In addition, as will be described in detail in an embodiment to be described later, a photodetector as a semiconductor device includes pixel circuits that convert signal charges photoelectrically converted by photoelectric conversion elements into pixel signals. The pixel circuits may include pixel transistors for different purposes. More specifically, the pixel circuits include pixel transistors such as selection transistors and reset transistors that function as switching elements and pixel transistor as amplification transistors that function as amplification elements.

In the amplification transistors, it is important to suppress deterioration in noise resistance with respect to 1/f noise, RIS noise, and the like compared to the pixel transistors (the selection transistors and the reset transistors) that function as switching elements.

The number of amplification transistors mounted on the photodetector, on the other hand, is smaller than that of the pixel transistors that function as switching elements, such as the selection transistors or the reset transistors.

By achieving the pixel transistors that function as switching elements, such as the selection transistor and the reset transistor, using the first field-effect transistor Q1 and achieving the amplification transistor using the second field-effect transistor Q2, therefore, it is possible to achieve high integration and improvement in noise resistance, and usability in a case of applying the present technology is high.

### Modifications of First Embodiment

Note that although a case where each of the first and second field-effect transistors Q1 and Q2 is of the n-channel conductivity type has been described in the above-described first embodiment, the present technology can also be applied to a case where each of the first and second field-effect transistors Q1 and Q2 is of the p-channel conductivity type.

In addition, the present technology can also be applied to a case where one of the first and second field-effect transistors Q1 and Q2 is of the p-channel conductivity type and the other is of the n-channel conductivity type.

In addition, although a case where each of the first and second field-effect transistors Q1 and Q2 is of the enhancement type has been described in the above-described first embodiment, the present technology can also be applied to a case where each of the first and second field-effect transistors Q1 and Q2 is of the depression type.

In addition, the present technology can also be applied to a case where one of the first and second field-effect transistors Q1 and Q2 is of the enhancement type and the other is of the depression type.

### Second Embodiment

A semiconductor device 1B according to a second embodiment of the present technology basically has a configuration similar to that of the semiconductor device 1A according to the above-described first embodiment, and the following configuration is different.

That is, as illustrated in FIGS. 1 and 2, the semiconductor device 1A according to the above-described first embodiment has a configuration where the first field-effect transistor Q1 and the second field-effect transistor Q2 are individually provided in different semiconductors 5 and 6.

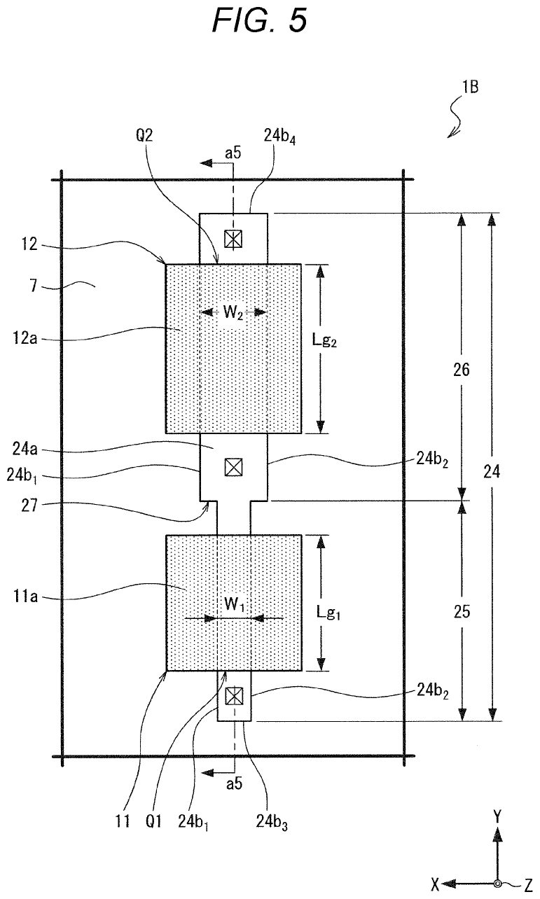

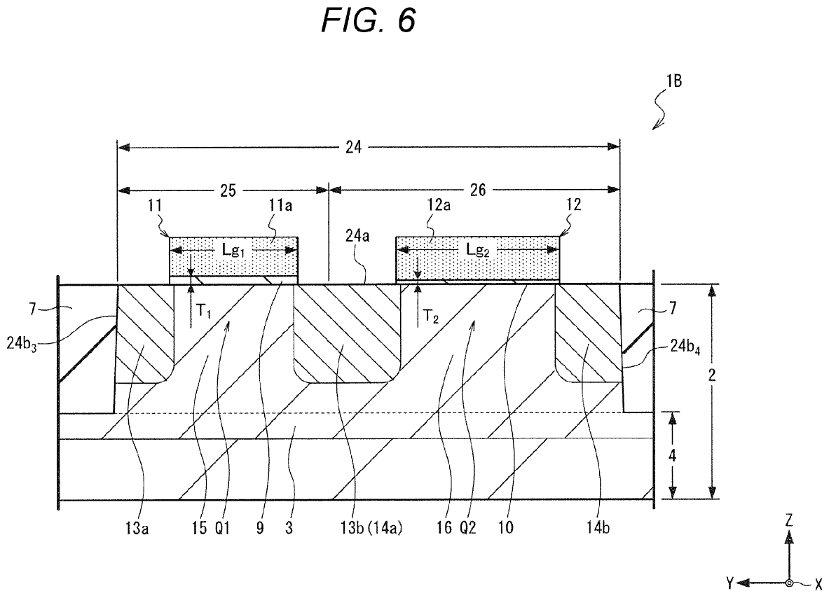

The semiconductor device 1B according to the second embodiment, on the other hand, has a configuration where, as illustrated in FIGS. 5 and 6, each of the first and second field-effect transistors Q1 and Q2 is provided in the same semiconductor 24. Other configurations are substantially similar to those in the first embodiment.

As illustrated in FIGS. 5 and 6, a semiconductor layer 2 according to the second embodiment includes a base 4 extending in two dimensions in the X and Y directions, and an island semiconductor 24 protruding upward (Z direction) from the base 4. The semiconductor 24 extends, for example, in the Y direction. In addition, the semiconductor 24 is a mesa-like rectangular parallelepiped having an upper surface 24a and four side surfaces 24b₁, 24b₂, 24b₃, and 24b₄. The semiconductor 24 also includes a first portion 25 extending in the Y direction and a second portion 26 extending in the Y direction from one end of the first portion 25 in a longitudinal direction (Y direction). A width W₁ of the upper surface 24a in the first portion 25 is smaller than a width W₂ of the upper surface 24a in the second portion 26. In other words, the width W₂ of the upper surface 24a in the second portion 26 is greater than the width W₁ of the upper surface 24a in the first portion 25. The semiconductor 24 also includes a step 27 between the first portion 25 and the second portion 26 where width of the semiconductor 24 in one direction (lateral direction) intersecting the longitudinal direction (Y direction) changes.

Among the four side surfaces 24b₁, 24b₂, 24b₃, and 24b₄ of the semiconductor 24, the two side surfaces 24b₁ and 24b₂ are located on opposite sides in the X direction, and the other two side surfaces 24b₃ and 24b₄ are located on opposite sides in the Y direction. Each of the four side surfaces 24b₁, 24b₂, 24b₃, and 24b₄ is also inclined such that an upper surface 24a side thereof is located inside a base 4 side thereof.

As illustrated in FIG. 6, the semiconductor layer 2 is provided with p-type well regions 3, which are, for example, p-type semiconductor regions. The p-type well regions 3 are provided all over the semiconductor 24 and provided all over a surface of the base 4 on a semiconductors 24 side of the base 4.

An insulating layer 7 is provided on the base 4 of the semiconductor layer 2 in such a way as to surround the semiconductor 24. A surface of the insulating layer 7 opposite a base 4 side of the semiconductor layer 2 is planarized, and the insulating layer 7 has a film thickness substantially equal to height (protrusion) of the semiconductor 24.

As illustrated in FIGS. 5 and 6, in the second embodiment, the first field-effect transistor Q1 is provided in the first portion 25 of the semiconductor 24. The second field-effect transistor Q2, on the other hand, is provided in the second portion 26 of the semiconductor 24. In addition, in the second embodiment, the channel formation portion 15, the gate electrode 11, and the gate insulating film 9 of the first field-effect transistor Q1 are provided in the first portion 25 of the semiconductor 24, and the channel formation portion 16, the gate electrode 12, and the gate insulating film 10 of the second field-effect transistor Q2 are provided in the first portion 25 of the semiconductor 24.

As illustrated in FIG. 5, the step 27 of the semiconductor 24 described above is provided between the gate electrode 11 of the first field-effect transistor Q1 and the gate electrode 12 of the second field-effect transistor Q2 in plan view. That is, the semiconductor 24 includes the step 27 between the gate electrode 11 of the first field-effect transistor Q1 and the gate electrode 12 of the second field-effect transistor Q2 where the width (W₁ or W₂) of the semiconductor 24 in one direction intersecting the longitudinal direction (Y direction) changes.

As illustrated in FIGS. 5 and 6, the gate electrode 11 according to the second embodiment has a configuration similar to that of the gate electrode 11 according to the above-described first embodiment. More specifically, the gate electrode 11 includes a head (first portion) 11a provided on the upper surface 5a of the semiconductor 24 via the gate insulating film 10 in the first portion 25 and two legs 11b₁ and 11b₂ (see FIG. 2 of the above-described first embodiment) integrated with the head 11a and provided outside each of the two side surfaces 24b₁ and 24b₂, which are located on opposite sides of the semiconductor 24 in the X direction, via the gate insulating film 9.

In addition, as illustrated in FIGS. 5 and 6, the gate electrode 12 according to the second embodiment, too, has a configuration similar to that of the gate electrode 12 according to the above-described first embodiment. More specifically, the gate electrode 12 includes a head (first portion) 12a provided on the upper surface 5a of the semiconductor 24 via the gate insulating film 9 in the second portion 26 and two legs 12b₁ and 12b₂ (refer to FIG. 2 in the above-described first embodiment) integrated with the head 12a and provided outside each of the two side surfaces 24b₁ and 24b₂, which are located on the opposite sides of the semiconductor 24 in the X direction, via the gate insulating film 10.

As illustrated in FIG. 6, in the second embodiment, too, the film thickness T₁ of the gate insulating film 9 of the first field-effect transistor Q1 is greater than the film thickness T₂ of the gate insulating film 10 of the second field-effect transistor Q2. In other words, the film thickness T₂ of the gate insulating film 10 of the second field-effect transistor Q2 is smaller than the film thickness T₁ of the gate insulating film 9 of the first field-effect transistor Q1.

As illustrated in FIG. 6, the first and second field-effect transistors Q1 and Q2 share the other main electrode region 13b of the first field-effect transistor Q1 and the main electrode region 14a of the second field-effect transistor Q2. That is, the first and second field-effect transistors Q1 and Q2 according to the second embodiment are provided in series in the semiconductor 24.

In the second embodiment, as described above, the width W₁ of the upper surface 24a of the semiconductor 24 overlapping the gate electrode 11 of the first field-effect transistor Q1 in the first portion 25 is smaller than the width W₂ of the upper surface 24a of the semiconductor 24 overlapping the gate electrode 12 of the second transistor Q2 in the second portion 26. In addition, the film thickness T₁ of the gate insulating film 9 of the first field-effect transistor Q1 is smaller than the film thickness T₂ of the gate insulating film 10 of the second field-effect transistor Q2.

The width W₂ of the upper surface 24a of the semiconductor 24 overlapping the gate electrode 12 of the second field-effect transistor Q2 in the second portion 26, on the other hand, is greater than the width W₁ of the upper surface 24a of the semiconductor 24 overlapping the gate electrode 11 of the first field-effect transistor Q1 in the first portion 25. In addition, the film thickness T₂ of the gate insulating film 10 of the second field-effect transistor Q2 is smaller than the film thickness Ti of the gate insulating film 9 of the first field-effect transistor Q1.

As a result, the semiconductor device 1B according to the second embodiment, too, can produce effects similar to those produced by the semiconductor device 1A according to the above-described first embodiment.

In addition, since the first and second field-effect transistors Q1 and Q2 according to the second embodiment share the other main electrode region 13b of the first field-effect transistor Q1 and the main electrode region 14a of the second field-effect transistor Q2, area occupied by a circuit including the first and second field-effect transistors Q1 and Q2 can be further reduced compared to area occupied by a circuit including the first and second field-effect transistors Q1 and Q2 according to the above-described first embodiment.

Note that, in the second embodiment, the semiconductor 24 corresponds to another specific example of the “semiconductor” in the present technology. In addition, the lateral direction (X direction) of the semiconductor 24 intersecting the longitudinal direction (Y direction) corresponds to another specific example of the “one direction of a semiconductor” in the present technology. In addition, the width W₁ of the semiconductor 24 in the first portion 25 and the width W₂ of the semiconductor 24 in the second portion 26 correspond to other specific examples of the “width of an upper surface of a semiconductor in one direction” in the present technology.

### Modifications of Second Embodiment

Note that although a case where each of the first and second field-effect transistors Q1 and Q2 is of the n-channel conductivity type has been described in the above-described second embodiment, the present technology can also be applied to a case where each of the first and second field-effect transistors Q1 and Q2 provided in the same semiconductor 24 is of the p-channel conductivity type.

In addition, the present technology can also be applied to a case where one of the first and second field-effect transistors Q1 and Q2 provided in the same semiconductor 24 is of the p-channel conductivity type and the other is of the n-channel conductivity type. In this case, however, the other main electrode region 13b of the first field-effect transistor Q1 and the main electrode region 14a of the second field-effect transistor Q2 need to be configured separately.

In addition, although a case where each of the first and second field-effect transistors Q1 and Q2 is of the enhancement type has been described in the above-described second embodiment, the present technology can also be applied to a case where each of the first and second field-effect transistors Q1 and Q2 provided in the same semiconductor 24 is of the depression type.

In addition, the present technology can also be applied to a case where one of the first and second field-effect transistors Q1 and Q2 provided in the same semiconductor 24 is of the enhancement type and the other is of the depression type.

### Third Embodiment

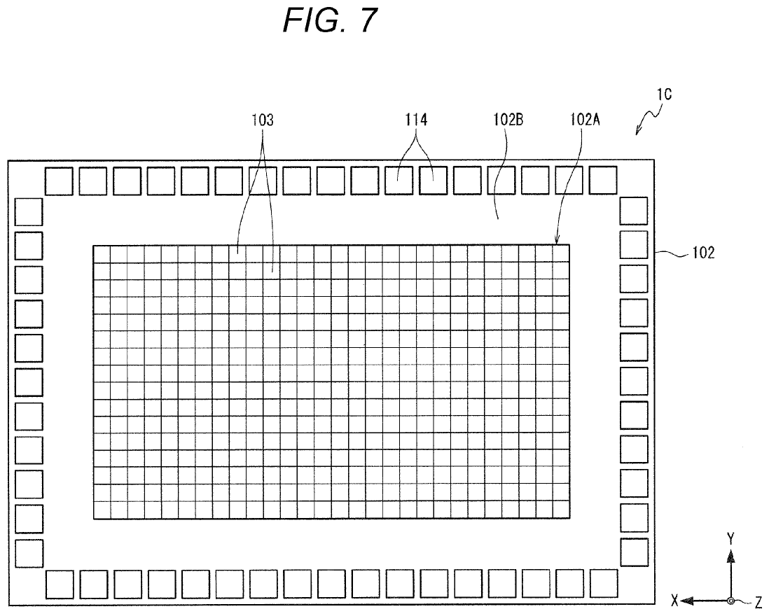

In this third embodiment, an example where the present technology is applied to a solid-state imaging device that is called a back-illuminated complementary metal-oxide semiconductor (CMOS) image sensor will be described as a photodetector included in a semiconductor device with reference to FIGS. 7 to 10.

### Overall Configuration of Solid-State Imaging Device

First, an overall configuration of a solid-state imaging device 1C will be described.

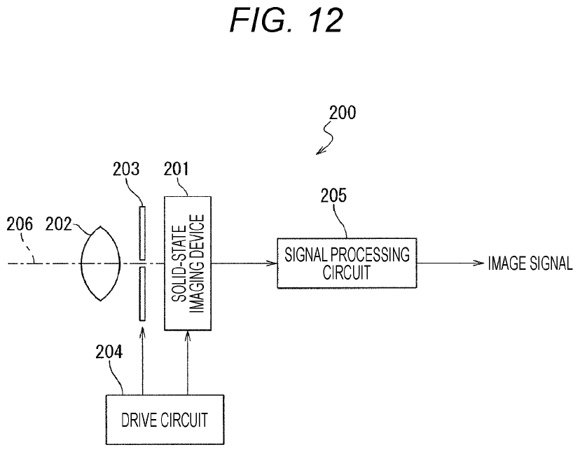

As illustrated in FIG. 7, the solid-state imaging device 1C according to the seventh embodiment of the present technology mainly includes a semiconductor chip 102 having a rectangular two-dimensional planar shape in plan view. That is, the solid-state imaging device 1C is mounted on the semiconductor chip 102, and the semiconductor chip 102 may be regarded as the solid-state imaging device 1C. As illustrated in FIG. 12, the solid-state imaging device 1C (201) receives image light (incident light 206) from a subject through an optical lens 202, converts an amount of the incident light 206 formed on an imaging plane as an image into an electrical signal for each pixel, and outputs the electrical signal as a pixel signal (image signal).

As illustrated in FIG. 7, the semiconductor chip 102 on which the solid-state imaging device 1C is mounted includes, in a two-dimensional plane including an X direction and a Y direction perpendicular to each other, a rectangular pixel array unit 102A provided in a central portion and a peripheral portion 102B provided outside the pixel array unit 102A in such a way as to surround the pixel array unit 102A. The semiconductor chip 2 is formed by fragmenting a semiconductor wafer including a semiconductor layer 2, which will be described later, for each chip formation region (solid-state imaging device) in a manufacturing process. Configuration of the solid-state imaging device 1C described below, therefore, is substantially similar even in a wafer state before the semiconductor wafer is fragmented. That is, the present technology can be applied in a state of a semiconductor chip and a state of a semiconductor wafer.

The pixel array unit 102A is, for example, a light receiving surface that receives light condensed by an optical lens (optical system) 202 illustrated in FIG. 12. In addition, a plurality of pixels 103 is arranged in the pixel array unit 102A in a matrix in the two-dimensional plane including the X direction and the Y direction. In other words, the pixels 103 are repeatedly disposed in the X direction and the Y direction perpendicular to each other in the two-dimensional plane.

As illustrated in FIG. 7, a plurality of bonding pads 114 is provided in the peripheral portion 102B. Each of the plurality of bonding pads 114 is disposed, for example, along each of four sides of the semiconductor chip 102 in the two-dimensional plane. Each of the plurality of bonding pads 114 functions as input/output terminals for electrically connecting the semiconductor chip 102 to an external device.

### Logic Circuit

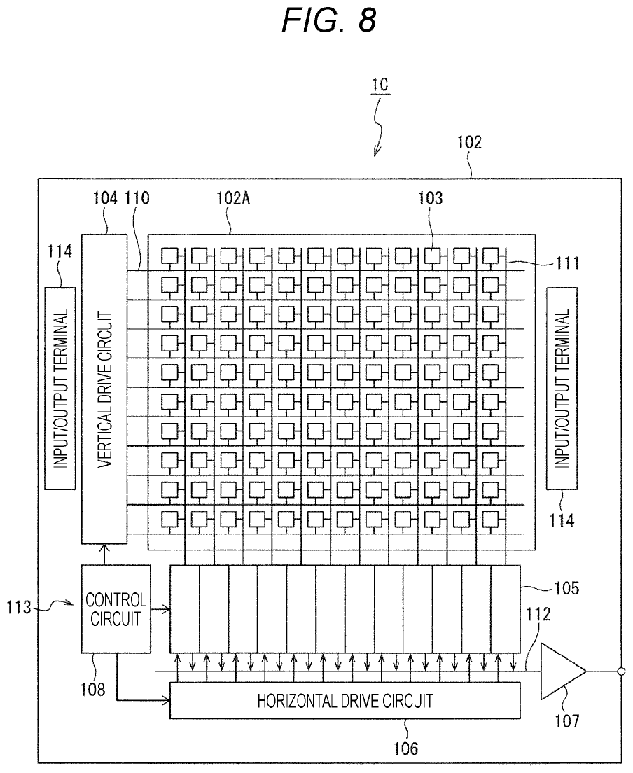

The semiconductor chip 102 includes a logic circuit 113 illustrated in FIG. 8. As illustrated in FIG. 8, the logic circuit 113 includes a vertical drive circuit 104, column signal processing circuits 105, a horizontal drive circuit 106, an output circuit 107, a control circuit 108, and the like. The logic circuit 113 includes, for example, a complementary MOS (CMOS) circuit including an n-channel conductive metal-oxide semiconductor field-effect transistor (MOSFET) and a p-channel conductive MOSFET as field-effect transistors.

The vertical drive circuit 104 includes, for example, a shift register. The vertical drive circuit 104 sequentially selects desired pixel drive lines 110 and supplies pulses for driving pixels 103 to the selected pixel drive lines 110 to drive the individual pixels 103 in units of rows. That is, the vertical drive circuit 104 selects and scans the individual pixels 103 in the pixel array unit 102A sequentially in a vertical direction in units of rows and supplies a pixel signal from each of the pixels 103 based on a signal charge generated by a photoelectric converter (photoelectric conversion element) of the pixel 103 in accordance with the amount of light received to a corresponding one of the column signal processing circuits 105 through a corresponding vertical signal line 111.

The column signal processing circuits 105 are each provided for one of columns of the pixels 103, for example, and perform signal processing, such as noise removal, on signals output from a corresponding row of pixels 103 for a corresponding pixel column. For example, the column signal processing circuits 105 perform signal processing such as correlated double sampling (CDS) for removing pixel-specific fixed pattern noise and analog digital (AD) conversion.

The horizontal drive circuit 106 includes, for example, a shift register. The horizontal drive circuit 106 sequentially outputs horizontal scanning pulses to the column signal processing circuits 105 to sequentially select the individual column signal processing circuits 105 and cause the individual column signal processing circuits 105 to output pixel signals obtained as a result of signal processing to a horizontal signal line 112.

The output circuit 107 performs signal processing on pixel signals sequentially supplied from the individual column signal processing circuits 105 through the horizontal signal line 112 and outputs the processed signals. As the signal processing, buffering, black level adjustment, column variation correction, various types of digital signal processing, and the like, for example, can be used.

The control circuit 108 generates clock signals and control signals that serve references for operation of the vertical drive circuit 104, the column signal processing circuits 105, the horizontal drive circuit 106, and the like on the basis of a vertical synchronization signal, a horizontal synchronization signal, and a master clock signal. The control circuit 108 then outputs the generated clock signals and control signals to the vertical drive circuit 104, the column signal processing circuits 105, the horizontal drive circuit 106, and the like.

### Circuit Configuration of Pixels

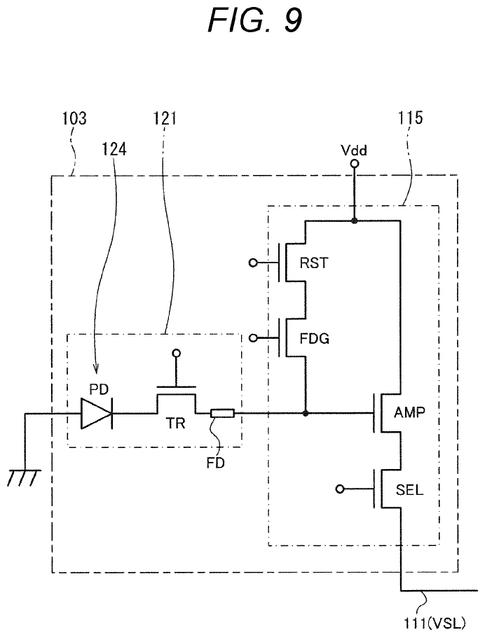

As illustrated in FIG. 9, each of the plurality of pixels 103 includes a photoelectric conversion region 121 and a pixel circuit (reading circuit) 115. The photoelectric conversion region 121 includes a photoelectric converter 124, a transfer transistor TR, and a charge holding region (floating diffusion) FD. The pixel circuit 115 is electrically connected to the charge holding region FD of the photoelectric conversion region 121. Although a circuit configuration where one pixel circuit 115 is allocated to one pixel 103 is employed in the third embodiment as an example, a circuit configuration to be employed is not limited to this. A circuit configuration where a plurality of pixels 103 shares one pixel circuit 115 may be employed, instead. For example, a circuit configuration may be employed where four pixels 103 in a two-by-two arrangement, in which two pixels are arranged in each of the X and Y directions, share one pixel circuit 115.

The photoelectric converter 124 illustrated in FIG. 9 is, for example, a photodiode (PD), which is of a p-n junction type, and generates signal charge according to the amount of light received. The photoelectric converter 124 includes a cathode side electrically connected to a source region of the transfer transistor TR and an anode side electrically connected to a reference potential line (e.g., ground).

The transfer transistor TR illustrated in FIG. 9 transfers the signal charge generated by the photoelectric converter 124 as a result of photoelectric conversion to the charge holding region FD. A source region of the transfer transistor TR is electrically connected to the cathode side of the photoelectric converter 124, and a drain region of the transfer transistor TR is electrically connected to the charge holding region FD. In addition, a gate electrode of the transfer transistor TR is electrically connected to a transfer transistor drive line among the pixel drive lines 110 (refer to FIG. 2).

The charge holding region FD illustrated in FIG. 9 temporarily holds (accumulates) the signal charge transferred from the photoelectric converter 124 via the transfer transistor TR.

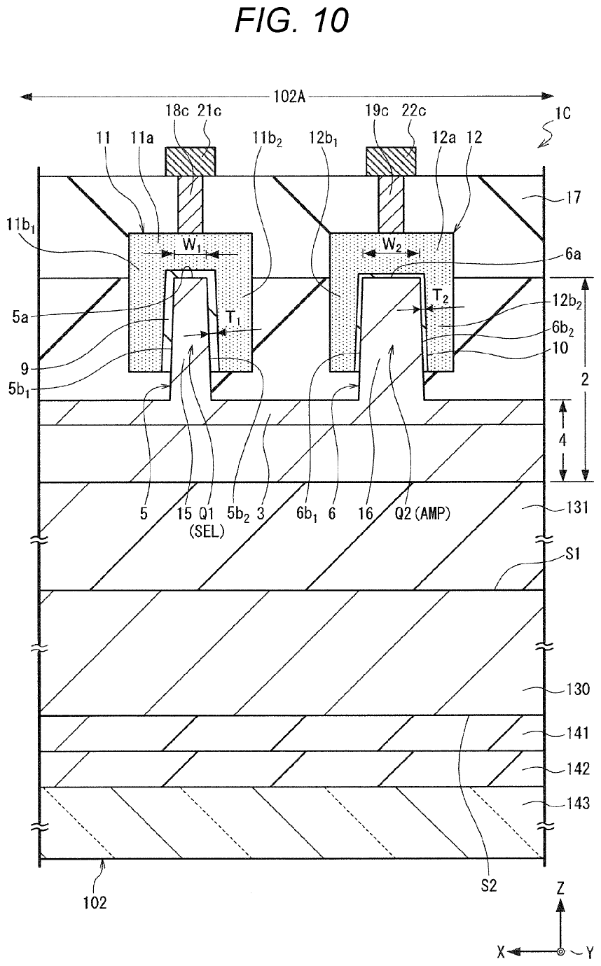

The photoelectric conversion region 121 including the photoelectric converter 124, the transfer transistor TR, and the charge holding region FD is mounted on a semiconductor layer 130 (refer to FIG. 10) as a second semiconductor layer, which will be described later.

The pixel circuit 115 illustrated in FIG. 9 reads the signal charge held in the charge holding region FD, converts the signal charge into a pixel signal based on the signal charge, and outputs the pixel signal. In other words, the pixel circuit 115 converts the signal charge generated by the photoelectric conversion element PD as a result of photoelectric conversion into a pixel signal based on the signal charge and outputs the pixel signal. Although not limited to this, the pixel circuit 115 includes, for example, an amplification transistor AMP, a selection transistor SEL, a reset transistor RST, and a switching transistor FDG as pixel transistors. Each of these pixel transistors (AMP, SEL, RST, and FDG) and the above-described transfer transistor TR is, for example, a MOSFET as a field-effect transistor. Alternatively, these transistors may be MISFETs.

Among the pixel transistors included in the pixel circuit 115, each of the selection transistor SEL, the reset transistor RST, and the switching transistor FDG functions as a switching element, and the amplification transistor AMP functions as an amplification element. That is, the pixel circuit 115 includes field-effect transistors for different purposes.

Note that the selection transistor SEL and the switching transistor FDG may be omitted as necessary.

As illustrated in FIG. 9, the amplification transistor AMP includes a source region electrically connected to a drain region of the selection transistor SEL and a drain region electrically connected to a power supply line Vdd and a drain region of the reset transistor RST. In addition, a gate electrode of the amplification transistor AMP is electrically connected to the charge holding region FD and a source region of the switching transistor FDG.

The selection transistor SEL includes a source electrically connected to a corresponding one of the vertical signal lines 111 (VSL) and the drain region electrically connected to a source region of the amplification transistor AMP. In addition, a gate electrode of the selection transistor SEL is electrically connected to a selection transistor drive line among the pixel drive lines 110 (refer to FIG. 8).

The reset transistor RST includes a source region electrically connected to a drain region of the switching transistor FDG and the drain region electrically connected to the power supply line Vdd and the drain region of the amplification transistor AMP. In addition, a gate electrode of the reset transistor RST is electrically connected to a reset transistor drive line among the pixel drive lines 110 (refer to FIG. 8).

The switching transistor FDG includes the source region electrically connected to the charge holding region FD and the gate electrode of the amplification transistor AMP and the drain region electrically connected to the power supply line Vdd and the drain region of the amplification transistor AMP. In addition, a gate electrode of the switching transistor FDG is electrically connected to a switching transistor drive line among the pixel drive lines 110 (refer to FIG. 8).

Note that in a case where the selection transistor SEL is omitted, the source region of the amplification transistor AMP is electrically connected to the corresponding one of the vertical signal lines (VSL) 111. In addition, in a case where the switching transistor FDG is omitted, the source region of the reset transistor RST is electrically connected to the gate electrode of the amplification transistor AMP and the charge holding region FD.

When turned on, the transfer transistor TR transfers the signal charge generated by the photoelectric converter 124 to the charge holding region FD.

When turned on, the reset transistor RST resets a potential (signal charge) of the charge holding region FD to a potential of the power supply line Vdd. The selection transistor SEL controls output timing of the pixel signal from the pixel circuit 115.

The amplification transistor AMP generates, as the pixel signal, a signal of a voltage corresponding to a level of the signal charge held in the charge holding region FD. The amplification transistor AMP constitutes a source follower amplifier and outputs a pixel signal of a voltage corresponding to a level of the signal charge generated by the photoelectric converter 124. When the selection transistor SEL is turned on, the amplification transistor AMP amplifies the potential of the charge holding region FD and outputs a voltage corresponding to the potential to the column signal processing circuit 105 via the corresponding one of the vertical signal lines (VSL) 111.

The switching transistor FDG controls the holding of charge by the charge holding region FD and adjusts a voltage amplification factor corresponding to the potential amplified by the amplification transistor AMP.

While the solid-state imaging device 1C according to the third embodiment is in operation, the signal charge generated by the photoelectric converter 124 of the pixel 103 is held (accumulated) by the charge holding region FD via the transfer transistor TR of the pixel 103. The signal charge held by the charge holding region FD is read by the pixel circuit 115 and applied to the gate electrode of the amplification transistor AMP of the pixel circuit 115. A horizontal line selection control signal is supplied from the vertical shift register to the gate electrode of the selection transistor SEL of the pixel circuit 115. By then setting the selection control signal to a high (H) level, the selection transistor SEL conducts to allow a current corresponding to the potential of the charge holding region FD amplified by the amplification transistor AMP to flow to the corresponding one of the vertical signal lines 111. In addition, by setting a reset control signal applied to the gate electrode of the reset transistor RST of the pixel circuit 115 to a high (H) level, the reset transistor RST conducts to reset the signal charge accumulated in the charge holding region FD.

### Longitudinal Cross-Sectional Structure of Solid-State Imaging Device

Next, a vertical cross-sectional structure of the semiconductor chip 102 (solid-state imaging device 1C) will be described with reference to FIG. 10. FIG. 10 is a schematic longitudinal cross-sectional view illustrating a longitudinal cross-sectional structure of the pixel array unit of FIG. 7, which is upside down with respect to FIG. 7 in order to make the drawing easy to see.

### Semiconductor Chip

As illustrated in FIG. 10, the semiconductor chip 102 includes the semiconductor layer 130 having a first surface S1 and a second surface S2 located on opposite sides in a thickness direction (Z direction), an insulating layer 131 provided on a first surface S1 side of the semiconductor layer 130, and the semiconductor layer 2 provided on the insulating layer 131 on a side opposite a semiconductor layer 130 side.

In addition, the semiconductor chip 102 includes, on a second surface S2 side of the semiconductor layer 130, a planarization layer 141, a color filter layer 142, a lens layer 143, and the like stacked in this order from the second surface S2 side.

The semiconductor layer 130 contains, for example, monocrystalline silicon.

The planarization layer 141 is, for example, a silicon oxide film. In addition, the planarization layer 141 covers the entire second surface S2 side of the semiconductor layer 130 in the pixel array unit 102A so that the second surface S2 (light incident surface) side of the semiconductor layer 130 becomes a flat surface without unevenness.

In the color filter layer 142, color filters such as red (R), green (G), and blue (B) are provided for each pixel 103 and color-separate incident light incident from the light incident surface side of the semiconductor chip 102.

In the lens layer 143, a microlens that condenses radiated light and efficiently causes the condensed light to enter the photoelectric conversion region 121 is provided for each pixel 103.

As illustrated in FIG. 10, the semiconductor layer 2 according to the third embodiment has a configuration similar to that of the semiconductor layer 2 according to the above-described first embodiment illustrated in FIG. 2, and the field-effect transistor Q1 is provided in the semiconductor 5 of the semiconductor layer 2, and the field-effect transistor Q2 is provided in the semiconductor 6 of the semiconductor layer 2. In addition, an insulating layer 7 is provided on the base 4 of the semiconductor layer 2 in such a way as to surround the semiconductors 5 and 6. The first and second field-effect transistors Q1 and Q2 according to the third embodiment have configurations similar to those of the first and second field-effect transistors Q1 and Q2 according to the above-described first embodiment.

Here, in the third embodiment, the semiconductor 5 corresponds to another specific example of the “semiconductor” in the present technology. In addition, a lateral direction (X direction) of the semiconductor 5 intersecting a longitudinal direction (Y direction) corresponds to another specific example of the “one direction of a semiconductor” in the present technology, and a lateral direction (X direction) of the semiconductor 6 intersecting a longitudinal direction (Y direction) corresponds to another specific example of the “one direction of a semiconductor” in the present technology.

In addition, in the third embodiment, a width W₁ of the semiconductor 5 and a width W₂ of the semiconductor 6 correspond to other specific examples of the “width of an upper surface of a semiconductor in one direction” in the present technology.

The semiconductor layer 130 overlaps the semiconductors 5 and 6 of the semiconductor layer 2. That is, the semiconductor chip 102 has a two-step structure where the semiconductor layer 130 and the semiconductor layer 2 are stacked in a thickness direction (Z direction) of each of these.

In the third embodiment, each of the photoelectric converter 124, the transfer transistor TR, and the charge holding region FD illustrated in FIG. 9 is provided in the semiconductor layer 130 illustrated in FIG. 10 although not illustrated in detail.

Each of the pixel transistors (AMP, SEL, RST, and FDG) included in the pixel circuit 115 of FIG. 9, on the other hand, is provided in the semiconductor layer 2 illustrated in FIG. 10 although not illustrated in detail. In addition, among the pixel transistors (AMP, SEL, RST, and FDG) included in the pixel circuit 115, the amplification transistor AMP, which functions as an amplification transistor, includes the second field-effect transistor Q2. In addition, among the pixel transistors (AMP, SEL, RST, and FDG) included in the pixel circuit 115, each of the selection transistor SEL, the reset transistor RST, and the switching transistor FDG, which function as switching elements, includes the first field-effect transistor Q1, although not illustrated in detail. FIG. 10 illustrates the selection transistor SEL as an example. Although not illustrated, each of the reset transistor RST and the switching transistor FDG is provided in another semiconductor different from the semiconductors 5 and 6. In addition, the other semiconductor, too, has a configuration similar to that of the semiconductor 5, and in terms used to describe the semiconductor 5, a width W₁ of an upper surface 5a is smaller than the width W₂ of the upper surface of the semiconductor 6.

That is, the pixel circuit 115 includes the amplification transistor AMP including the second field-effect transistor Q2 and the pixel transistors (AMP, SEL, RST, and FDG) as switching elements (switching transistors) electrically connected to the amplification transistor AMP and including the first field-effect transistor Q1.

### Main Effects in the Third Embodiment

As described above, in the solid-state imaging device 1C according to the third embodiment, the selection transistor SEL, which functions as a switching element, among the pixel transistors included in the pixel circuit 115 includes the first field-effect transistor Q1 provided in the semiconductor 5. In addition, among the pixel transistors included in the pixel circuit 115, each of the reset transistor RST and the switching transistor FDG, which function as switching elements, includes the first field-effect transistor Q1 provided in another semiconductor having a configuration similar to that of the semiconductor 5. Furthermore, among the pixel transistors included in the pixel circuit 115, the amplification transistor AMP, which functions as an amplification element, includes the second field-effect transistor Q2 provided in the semiconductor 6.

As a result, the solid-state imaging device 1C according to the third embodiment, too, can produce effects similar to those produced by the semiconductor device 1A according to the above-described first embodiment.

Here, in the amplification transistor AMP, it is important to suppress deterioration of noise resistance with respect to 1/f noise, RTS noise, and the like compared to the pixel transistors (SEL, RST, and FDG), which function as switching elements.

The number of amplification transistors AMP provided in the pixel array unit 2A, on the other hand, is smaller than that of pixel transistors, which include the selection transistor SEL, the reset transistor RST, and the switching transistor FDG, which function as switching elements.

By achieving the pixel transistors that function as switching elements, such as the selection transistor SEL, the reset transistor RST, and the switching transistor FDG, using the first field-effect transistor Q1 and achieving the amplification transistor AMP using the second field-effect transistor Q2, therefore, it is possible to achieve high integration and improvement in noise resistance, and usability in a case of applying the present technology is high.

In addition, since the pixel transistors included in the pixel circuit 115 are provided in the semiconductor layer 2 different from the semiconductor layer 130 provided with the photoelectric converter 124, the transfer transistor TR, and the charge holding region FD, a degree of freedom in arrangement of the pixel transistors (AMP, SEL, RST, and FDG) included in the pixel circuit 115 can be increased, and it is possible to achieve higher integration and further improvement in noise resistance compared to a case where the photoelectric converter 124, the transfer transistor TR, the charge holding region FD, and the pixel transistors are provided in the same semiconductor layer.

### Modifications of Third Embodiment

Note that at least one of the pixel transistors (SEL, RST, and FDG) as switching elements included in the pixel circuit 115 may include the field effect-transistor Q1.

In addition, among the pixel transistors (AMP, SEL, RST, and FDG) included in the pixel circuit 115, at least one of the selection transistor SEL, the reset transistor RST, or the switching transistor FDG may include the first field-effect transistor Q1 illustrated in FIGS. 5 and 6, and the amplification transistor AMP may include the second field-effect transistor Q2 illustrated in FIGS. 5 and 6.

In addition, a plurality of switching elements including the first field-effect transistor Q1 may be provided in the first portion 25 of the semiconductor 24 illustrated in FIGS. 5 and 6, and the amplification transistor AMP including the second field-effect transistor Q2 may be provided in the second portion 26.

### Fourth Embodiment

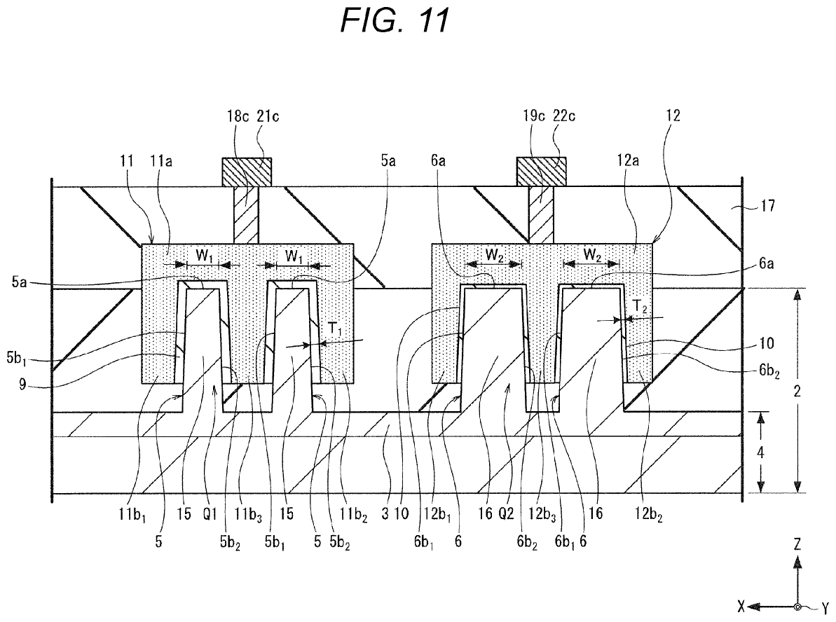

In the above-described first to third embodiments, the gate electrode 11 including the head 11a and the two legs 11b₁ and 11b₂ and the gate electrode 12 including the head 12a and the two legs 12b₁ and 12b₂ have been described. The number of legs of the gate electrodes 11 and 12, however, is not limited to two. As illustrated in FIG. 11, for example, the gate electrode 11 may include three legs 11b₁, 11b₂, and 11b₃, and the gate electrode 12 may include three legs 12b₁, 12b₂, and 12b₃, instead. Alternatively, although not illustrated, the gate electrode 11 may include four or more legs, and the gate electrode 12 may include four or more legs. In this case, the number of semiconductors 5 (first portions 25 of the semiconductor 24) is n−1 when the number of legs of the gate electrode 11 is n, and the number of semiconductors 6 (second portions 26 of the semiconductor 24) is n−1 when the number of legs of gate electrode 12 is n. In this case, too, the present technology can be applied.

### Fifth Embodiment

### Examples of Application to Electronic Apparatus

The present technology (the technology in the present disclosure) can be applied, for example, to various electronic apparatuses including imaging apparatuses such as a digital still camera and a digital video camera, mobile phones having an imaging function, and other apparatuses having an imaging function.

FIG. 12 is a diagram illustrating a schematic configuration of an electronic apparatus (e.g., a camera) according to a fifth embodiment of the present technology.

As illustrated in FIG. 12, an electronic apparatus 200 includes a solid-state imaging device 201, an optical lens 202, a shutter device 203, a drive circuit 204, and a signal processing circuit 205. The electronic apparatus 200 is an embodiment in a case where the solid-state imaging device 1C according to the third embodiment of the present technology is used for an electronic apparatus (e.g., a camera) as the solid-state imaging device 201.

The optical lens 202 forms an image of image light (incident light 206) from a subject on an imaging plane of the solid-state imaging device 201. As a result, signal charges are accumulated in the solid-state imaging device 201 over a certain period of time. The shutter device 203 controls a light radiation period and a light blocking period for the solid-state imaging device 201. The drive circuit 204 supplies a drive signal for controlling a transfer operation by the solid-state imaging device 201 and a shutter operation by the shutter device 203. Signal transfer of the solid-state imaging device 201 is performed in accordance with the drive signal (timing signal) supplied from the drive circuit 204. The signal processing circuit 205 performs various types of signal processing on a signal (pixel signal (image signal) output from the solid-state imaging device 201. An image signal subjected to the signal processing is stored into a storage medium such as a memory, or is output to a monitor.

With this configuration, since high integration and improvement in noise resistance are achieved in the solid-state imaging device 201 of the electronic apparatus 200 according to the ninth embodiment, image quality can be improved.

Note that the electronic apparatus 200 to which the solid-state imaging device according to one of the above-described embodiments can be applied is not limited to a camera, and the solid-state imaging device can also be applied to other electronic apparatuses. For example, the solid-state imaging device may be applied to an imaging apparatus such as a camera module for a mobile apparatus such as a mobile phone or a tablet terminal.

In addition, the present technology can be applied to photodetectors in general including not only the above-described solid-state imaging devices as image sensors but also distance measurement sensors that are also called time of flight (ToF) sensors and that measure a distance and the like. A distance measurement sensor is a sensor that emits radiation light to an object, that detects reflected light, which is the radiation light reflected from a surface of the object, and that calculates a distance to the object on the basis of time of flight from the emission of the radiation light to reception of the reflected light. As structure of an element isolation region of the distance measurement sensor, structure of the element isolation region described above may be employed.

### Other Embodiments

In the above-described first embodiment, a case has been described where the first and second field-effect transistors Q1 and Q2 are individually provided in the rectangular parallelepiped semiconductors 5 and 6, respectively, extending in the Y direction has been described. The present technology, however, is not limited to the rectangular parallelepiped semiconductors 5 and 6.

For example, the present technology can also be applied to a field-effect transistor in which a channel formation portion and a gate electrode are provided at a corner of a semiconductor having an L-shaped planar shape.

In addition, in the above-described first to fourth embodiments, the island semiconductors 5, 6, and 24 integrated with the base 4 of the semiconductor layer 2 have been described as semiconductors. The present technology, however, is not limited to the island semiconductors 5, 6, and 24 integrated with the base 4.

For example, the present technology can also be applied to a silicon on insulator (SOI) structure in which a semiconductor is provided on an insulating layer. In this case, the semiconductor has a bottom surface in contact with the insulating layer on a side opposite an upper surface.

Note that the present technology may also have the following configurations.
(1)

A semiconductor device including:
first and second field-effect transistors,
in which each of the first and second field-effect transistors includes
a channel formation portion provided in a semiconductor including an upper surface and side surfaces,
a gate electrode provided over the upper surface and the side surfaces in one direction of the semiconductor, and
a gate insulating film provided between the semiconductor and the gate electrode,
a width, in the one direction, of the upper surface of the semiconductor layer overlapping the gate electrode of the first transistor is smaller than a width, in the one direction, of the upper surface of the semiconductor layer overlapping the gate electrode of the second transistor, and
a film thickness of the gate insulating film of the second transistor is smaller than a film thickness of the gate insulating film of the first transistor.
(2)

The semiconductor device according to (1), in which the first field-effect transistor and the second field-effect transistor are provided in different semiconductors.
(3)

The semiconductor device according to (1), in which each of the first and second field-effect transistors is provided in the same semiconductor.
(4)

The semiconductor device according to (3), in which
each of the first and second field-effect transistors further includes a pair of main electrode regions provided in the semiconductor on both sides of the gate electrode in a gate length direction, and
the first and second field-effect transistors share one of the pair of main electrode regions.
(5)

The semiconductor device according to (3) or (4), in which the semiconductor includes a step between the gate electrodes of the first and second field-effect transistors where width in the one direction changes.
(6)

The semiconductor device according to any one of (1) to (5), in which
the first field-effect transistor is a switching element, and
the second field-effect transistor is an amplification transistor.
(7)

The semiconductor device according to any one of (1) to (5), further including:
a photoelectric conversion element; and a pixel circuit that converts signal charge generated by the photoelectric conversion element as a result of photoelectric conversion into a pixel signal,
in which the pixel circuit includes an amplification transistor including the second field-effect transistor and a switching element electrically connected to the amplification transistor and including the first field-effect transistor.
(8)

The semiconductor device according to (7), further including: a semiconductor layer overlapping the semiconductor in plan view and provided with the photoelectric conversion element.
(9)

The semiconductor device according to any one of (1) to (8), in which one of the first and second field-effect transistors is of a p-channel conductivity type and the other is of an n-channel conductivity type.
(10)

The semiconductor device according to any one of (1) to (9), in which a gate length of the second gate electrode is greater than a gate length of the first gate electrode.
(11)

The semiconductor device according to any one of (1) to (10), in which a gate length of the first field-effect transistor is 200 nm or less.
(12)

The semiconductor device according to any one of (1) to (11), in which a difference between a width of the first field-effect transistor on the upper surface of the semiconductor layer and a width of the second field-effect transistor on the upper surface of the semiconductor layer is 10 nm or more.
(13)

The semiconductor device according to any one of (1) to (12), in which a difference in film thickness between the gate insulating film of the first field-effect transistor and the gate insulating film of the second field-effect transistor is 1 nm or more on the upper surface of the semiconductor layer.
(14)

An electronic apparatus including:
a semiconductor device;
an optical lens that forms an image of image light from a subject on an imaging plane of the semiconductor device; and
a signal processing circuit that performs signal processing on a signal output from the semiconductor layer,
in which the semiconductor device includes
first and second field-effect transistors for different purposes,
each of the first and second field-effect transistors includes
a channel formation portion provided in a semiconductor including an upper surface and side surfaces,
a gate electrode provided over the upper surface and the side surfaces in one direction of the semiconductor, and
a gate insulating film provided between the semiconductor and the gate electrode,
a width, in the one direction of the upper surface of the semiconductor layer overlapping the gate electrode of the first transistor is smaller than a width, in the one direction, of the upper surface of the semiconductor layer overlapping the gate electrode of the second transistor, and
a film thickness of the gate insulating film of the second transistor is smaller than a film thickness of the gate insulating film of the first transistor.

The scope of the present technology is not limited to the exemplary embodiments illustrated in the drawings and described above, and also includes all embodiments that produce effects equivalent to those that the present technology intends to produce. Furthermore, the scope of the present technology is not limited to combinations of features of the invention defined by the claims, and may be defined by any desired combination of specific features among all the disclosed features.

### REFERENCE SIGNS LIST

1A, 1B Semiconductor device
1C Solid-state imaging device
2 Semiconductor layer
3 Well regions
4 Base
5 Semiconductor
5a Upper surface
5c₁, 5c₂, 5c₃, 5c₄ Side surface
6 Semiconductor
6a Upper surface
6c₁, 6c₂, 6c₃, 6c₄ Side surface
7 Insulating layer
9, 10 Gate insulating film
11, 12 Gate electrode
11a, 12a Head (first portion)
11b₁, 11b₂, 11b₃, 12b₁, 12b₂, 12b₃ Leg (second portion)
13a, 13b, 14a, 14b Main electrode region
15, 16 Channel formation portion
17 Insulating layer
18a, 18b, 18c Contact electrode
19a, 19b, 19c Contact electrode
21a, 21b, 21c Wire
22a, 22b, 22c Wire
24 Semiconductor
24a Upper surface
24b₁, 24b₂, 24b₃, 24b₄ Side surface
25 First portion
26 Second portion
102 Semiconductor chip
102A Pixel array unit
102B Peripheral portion
103 Pixels
104 Vertical drive circuit
105 Column signal processing circuits
106 Horizontal drive circuit
107 Output circuit
108 Control circuit
110 Pixel drive lines
111 Vertical signal lines
113 Logic circuit
114 Bonding pads
115 Reading circuit
130 Semiconductor layer (second semiconductor layer)
131 Wiring layer
141 Planarization layer
142 Filter layer
143 Lens layer
200 Electronic apparatus
201 Solid-state imaging device
202 Optical lens
203 Shutter device
204 Drive circuit
205 Signal processing circuit
206 Incident light
AMP Amplification transistor
FD Charge holding region
FDG Switching transistor
PD Photoelectric conversion element
RST Reset transistor
SEL Selection transistor
TR Transfer transistor

1. A semiconductor device comprising:
first and second field-effect transistors,
wherein each of the first and second field-effect transistors includes
a channel formation portion provided in a semiconductor including an upper surface and side surfaces,
a gate electrode provided over the upper surface and the side surfaces in one direction of the semiconductor, and
a gate insulating film provided between the semiconductor and the gate electrode,
a width, in the one direction, of the upper surface of the semiconductor layer overlapping the gate electrode of the first transistor is smaller than a width, in the one direction, of the upper surface of the semiconductor layer overlapping the gate electrode of the second transistor, and
a film thickness of the gate insulating film of the second transistor is smaller than a film thickness of the gate insulating film of the first transistor.

2. The semiconductor device according to claim 1, wherein the first field-effect transistor and the second field-effect transistor are provided in different semiconductors.

3. The semiconductor device according to claim 1, wherein each of the first and second field-effect transistors is provided in the same semiconductor.

4. The semiconductor device according to claim 1, wherein
each of the first and second field-effect transistors further includes a pair of main electrode regions provided in the semiconductor on both sides of the gate electrode in a gate length direction, and
the first and second field-effect transistors share one of the pair of main electrode regions.

5. The semiconductor device according to claim 3, wherein the semiconductor includes a step between the gate electrodes of the first and second field-effect transistors where width in the one direction changes.

6. The semiconductor device according to claim 1, wherein
the first field-effect transistor is a switching element, and
the second field-effect transistor is an amplification transistor.

7. The semiconductor device according to claim 1, further comprising:
a photoelectric conversion element; and a pixel circuit that converts signal charge generated by the photoelectric conversion element as a result of photoelectric conversion into a pixel signal,
wherein the pixel circuit includes an amplification transistor including the second field-effect transistor and a switching element electrically connected to the amplification transistor and including the first field-effect transistor.

8. The semiconductor device according to claim 7, further comprising: a semiconductor layer overlapping the semiconductor in plan view and provided with the photoelectric conversion element.

9. The semiconductor device according to claim 1, wherein one of the first and second field-effect transistors is of a p-channel conductivity type and the other is of an n-channel conductivity type.

10. The semiconductor device according to claim 1, wherein a gate length of the second gate electrode is greater than a gate length of the first gate electrode.

11. The semiconductor device according to claim 1, wherein a gate length of the first field-effect transistor is 200 nm or less.

12. The semiconductor device according to claim 1, wherein a difference between a width of the first field-effect transistor on the upper surface of the semiconductor layer and a width of the second field-effect transistor on the upper surface of the semiconductor layer is 10 nm or more.

13. The semiconductor device according to claim 1, wherein a difference in film thickness between the gate insulating film of the first field-effect transistor and the gate insulating film of the second field-effect transistor is 1 nm or more on the upper surface of the semiconductor layer.

14. An electronic apparatus comprising:
a semiconductor device;
an optical lens that forms an image of image light from a subject on an imaging plane of the semiconductor device; and
a signal processing circuit that performs signal processing on a signal output from the semiconductor layer,
wherein the semiconductor device includes
first and second field-effect transistors for different purposes,
each of the first and second field-effect transistors includes
a channel formation portion provided in a semiconductor including an upper surface and side surfaces,
a gate electrode provided over the upper surface and the side surfaces in one direction of the semiconductor, and
a gate insulating film provided between the semiconductor and the gate electrode,
a width, in the one direction of the upper surface of the semiconductor layer overlapping the gate electrode of the first transistor is smaller than a width, in the one direction, of the upper surface of the semiconductor layer overlapping the gate electrode of the second transistor, and
a film thickness of the gate insulating film of the second transistor is smaller than a film thickness of the gate insulating film of the first transistor.
